(19) United States
(12) Patent Application Publication
(10) Pub. No.: US 2025/0139722 A1
(43) Pub. Date: May 1, 2025

(54) PARAMETRIC COST-MODELING SYSTEM

(71) Applicant: Protea Intelligence, Inc., Santa Monica, CA (US)

(72) Inventors: Arman Nadershahi, Porter Ranch, CA (US); Christopher Sterpan, Pacific Palisades, CA (US); Stephen Faust, Conifer, CO (US)

(21) Appl. No.: 18/694,258

(22) PCT Filed: Sep. 21, 2022
(86) PCT No.: PCT/US2022/044244

§ 371 Date: Mar. 21, 2024

Related U.S. Application Data
(60) Provisional application No. 63/246,462, filed on Sep. 21, 2021.

(51) Int. Cl. G06Q 50/16; G06F 30/13; G06Q 10/0631

(52) U.S. Cl. CPC G06Q 50/165; G06F 30/13; G06Q 10/06313

(57) ABSTRACT

A cost modeling system typically used for construction projects reliant on 3D computer aided design (CAD) files. It enables a computing system to rapidly generate accurate, real-time parametric cost models of proposed building designs based on either data inputs from users or a from a three-dimensional model, or various combinations thereof, which may then be presented to a user of the computer system (e.g., a construction professional). Data may be inherently stored within the CAD file properties itself or may be selectively input by the end user or a combination thereof.

### CROSS-REFERENCE TO RELATED APPLICATION

This application is a 371 national stage filing and claims priority in International Application No. PCT/US2022/044244 Filed Sep. 21, 2022, which claims priority in U.S. Provisional Patent Application No. 63/246,462 Filed Sep. 21, 2021, which is incorporated herein by reference.

### BACKGROUND OF THE INVENTION

### 1. Field of the Invention

The present invention relates generally to a cost modeling system and method for use thereof, and more specifically to a software tool that enables a computing device to rapidly and parametrically determine the cost of a building represented by inputs corresponding with a three-dimensional drawing.

### 2. Description of the Related Art

During the typical bidding or design phases of construction projects, designers or owners of planned buildings typically do not have accurate estimates of the costs of building designs. Designers and owners typically cannot rapidly obtain accurate, real-time parametric cost models of proposed building designs.

In addition, in a typical construction design, a set of construction plan drawings are generated, usually with a computer-implemented tool, such as an architectural CAD (Computer Aided Design) software product. Disadvantageously, the designer or owner of the building does not know the estimated cost of the building that they are designing, particularly while they are making a plurality of changes to the design of the building. Often, the cost of designs are estimated separately from the design process. This separate process very disadvantageously adds a significant amount of time and effort to the process of generating a construction job price. Also very disadvantageously, because different construction programs can generally be used on the same construction job or project, the cost amounts that are set forth on a price schedule that is generated by this separate process can vary by a very wide margin. Further, and also disadvantageously, in the event that the price schedule needs to be changed, for example, due to cost overruns, competitive bidding and/or other factors, a new price schedule must be generated, with an additional significant investment of time and effort involved for each such revision. Again, this adds a significant amount of extra expense to a construction project, and this typical process limits the flexibility in selected various construction materials for contractors and end-use customers.

Heretofore there has not been available a system or method for a cost modeling system with the advantages and features of the present invention.

### BRIEF SUMMARY OF THE INVENTION

The present invention generally provides a cost modeling system typically used for construction projects reliant on 3D computer aided design (CAD) files. It enables a computing system to rapidly generate accurate, real-time parametric cost models of proposed building designs based on either data inputs from users or a from a three-dimensional model, or various combinations thereof, which may then be presented to a user of the computer system (e.g., a construction professional).

For instance, in one implementation, the disclosed software technology may cause a computing device to engage in the following operations: (1) receive instructions for the three-dimensional design of a building; (2) compile a dataset that defines the three-dimensional drawing; and (3) rapidly generate accurate, real-time parametric cost models of proposed building designs based on data from the compiled data set, from a user of the software, or from a combination thereof. However, it should be understood that the disclosed software technology for generating cost models based on a three-dimensional model, user inputs, or a combination thereof, may cause a computing system to perform various other operations as well.

Also disclosed herein is software technology that enables a computing system to use a three-dimensional model as a basis for generating an estimate of the cost of the building and various components, systems, or programs of the building, which may then be presented to a user of the computing system (e.g., a construction professional).

Also disclosed herein is software technology that enables a computing system to use a three-dimensional model as a basis for generating an estimate of the cost of the building and various components, systems, or programs of the building, which may then be presented to a user of the computing system (e.g., a construction professional).

Additionally, disclosed herein is a software tool that enables a computing device to render a three-dimensional model of a building based on the input of numerous design parameters in a data-input computer interface.

In another aspect, disclosed herein is a computing system that comprises at least one processor, a non-transitory computer-readable medium, and program instructions stored on the non-transitory computer-readable medium that are executable by the at least one processor to cause the computing system to carry out the operations disclosed herein, including but not limited to the operations of the foregoing method.

In yet another aspect, disclosed herein is a non-transitory computer-readable medium comprising program instructions that are executable to cause a computing system to carry out the operations disclosed herein, including but not limited to the operations of the foregoing method.

These, as well as other components, steps, features, objects, benefits, and advantages, will now become clear from a review of the following detailed description of illustrative embodiments, the accompanying drawings, and the claims.

### BRIEF DESCRIPTION OF THE DRAWINGS

The drawings constitute a part of this specification and include exemplary embodiments of the present invention illustrating various objects and features thereof.

FIG. 1 shows a user interface featuring a three-dimensional building drawing prepared using computer aided design (CAD) software and includes cost estimate outputs.

FIG. 2 shows a user interface showing data inputs and various levels being displayed to the end user.

FIG. 3 shows a user interface of a cost estimate output.

FIG. 4 is a flow diagram depicting steps taken in practicing an embodiment of the present invention.

FIG. 5 is another flow diagram depicting steps taken in practicing an embodiment of the present invention.

FIG. 6 is yet another flow diagram depicting steps taken in practicing an embodiment of the present invention.

FIG. 7 is yet another flow diagram depicting steps taken in practicing an embodiment of the present invention.

FIG. 8 is yet another flow diagram depicting steps taken in practicing an embodiment of the present invention.

FIG. 9 is yet another flow diagram depicting steps taken in practicing an embodiment of the present invention.

FIG. 10 is yet another flow diagram depicting steps taken in practicing an embodiment of the present invention.

### DETAILED DESCRIPTION OF THE PREFERRED EMBODIMENTS

### I. Introduction and Environment

As required, detailed aspects of the present invention are disclosed herein, however, it is to be understood that the disclosed aspects are merely exemplary of the invention, which may be embodied in various forms. Therefore, specific structural and functional details disclosed herein are not to be interpreted as limiting, but merely as a basis for the claims and as a representative basis for teaching one skilled in the art how to variously employ the present invention in virtually any appropriately detailed structure.

Certain terminology will be used in the following description for convenience in reference only and will not be limiting. For example, up, down, front, back, right and left refer to the invention as orientated in the view being referred to. The words, “inwardly” and “outwardly” refer to directions toward and away from, respectively, the geometric center of the aspect being described and designated parts thereof. Forwardly and rearwardly are generally in reference to the direction of travel, if appropriate. Said terminology will include the words specifically mentioned, derivatives thereof and words of similar meaning.

### II. Preferred Embodiment Parametric Cost-Modeling Software System

In an exemplary embodiment, the computer system obtains all, or various combinations, of the following parametric values from a user. In some embodiments, some of the values may be obtained without user input. Some calculations are also included below. The values and calculations may be used to determine the cost of a building. In some embodiments, the sum values are entered manually while others are obtained automatically from other values below. The software may use the values to cause the computer to determine the cost of the building. The cost modeling can be done in real-time. The cost modelling can be done dynamically.

For instance, in one implementation, the disclosed software technology may cause a computing device to engage in the following operations: (1) receive data about various design parameters of a building inputted into the software by a user; and (2) rapidly generate accurate, real-time parametric cost models of proposed building designs based on the compiled data set. In various embodiments the data for the design of the building can be received from a user of the software, automatically from another data source, or combinations thereof. In an exemplary embodiment, the inputs and compiled data may comprise of the following information and calculations:

### III. Cost-Modeling Software System Utilizing 3D Building Design

In an exemplary embodiment, the computer system obtains all, or various combinations, of the following parametric values from a 3D CAD drawing of a building. In some embodiments, some of the values may be obtained without user input. The values and calculations may be used to determine the cost of a building. In some embodiments, the sum values are entered manually while others are obtained automatically from the 3D drawing. The software may use the values to cause the computer to determine the cost of the building. The cost modeling can be done in real-time. The cost modelling can be done dynamically.

For instance, in one implementation, the disclosed software technology may cause a computing device to engage in the following operations: (1) receive data for the three dimensional design of a building; (2) compile a dataset based on data from the three-dimensional drawing, from additional data inputted into the software by a user, or from a combination of the three dimensional drawing and the data separately inputted into the software by a user; and (3) rapidly generate accurate, real-time parametric cost models of proposed building designs based on the compiled data set. In various embodiments the data for the three-dimensional design of the building can be received from a user of the software, automatically from another data source, or combinations thereof. The inputs and compiled data may comprise information and calculations similar to those of Example 1, paragraph [0027] supra.

In an exemplary embodiment, the 3D modeling software sends the following information to the parametric cost modeling software: gross floor area, number of levels, below grade levels, above grade levels, basement floor to floor heights, above grade floor to floor heights, floor plate width, and footprint area. In another exemplary embodiment, it sends the preceding information as well as additional information.

In an exemplary embodiment, the parametric cost modeling software sends information to the 3D CAD software in order to instruct the CAD software and computer to generate a massing model. In an exemplary embodiment, the parametric cost modeling software sends information to the 3D CAD software in order to modify the CAD file. For example, in an exemplary embodiment, the parametric cost modeling software may send information that the Revit uses to modify at least one of the following file types: RTE, RVT, RFA, and RFT. In another exemplary embodiment, the parametric cost modeling software may send information that the Revit uses to modify at least one of the following file types: GN, DWF, DWG, DXF, IFC, SAT, and SKP. In yet another exemplary embodiment, the parametric cost modeling software may send information that the Revit uses to modify at least one of the following file types: ODBC, HTML, TXT, and gbXML.

In an exemplary embodiment, the information exchanged between the CAD software and the parametric cost modeling software is in the form of JSON files. In another exemplary embodiment, the information exchanged between the CAD software and the parametric cost modeling software is via APIs.

In an exemplary embodiment, the 3D drawing software is Revit. In another exemplary embodiment the 3D drawing software is Rhino. In another exemplary embodiment the 3D drawing software is SketchUp.

In an exemplary embodiment, the 3D drawing software is installed onto the hard drive of the computer, while the cost estimating software is hosted in remote servers and accessed using an internet browser installed on a user's local hard drive or local flash drive, or accessed by a mobile device software application. In another exemplary embodiment, both the CAD software and the parametric cost modeling software are installed on the end user's computer. In another exemplary embodiment, both the CAD software and the parametric cost modeling software are installed in a remote server from the end user and accessed via an internet browser or mobile application.

### IV. Estimation Software System 800

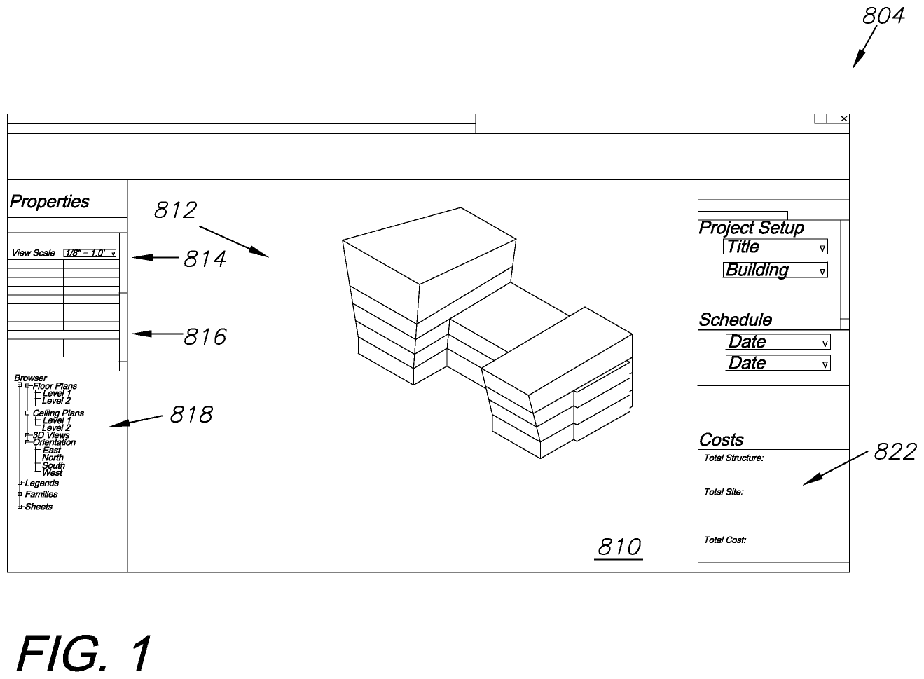

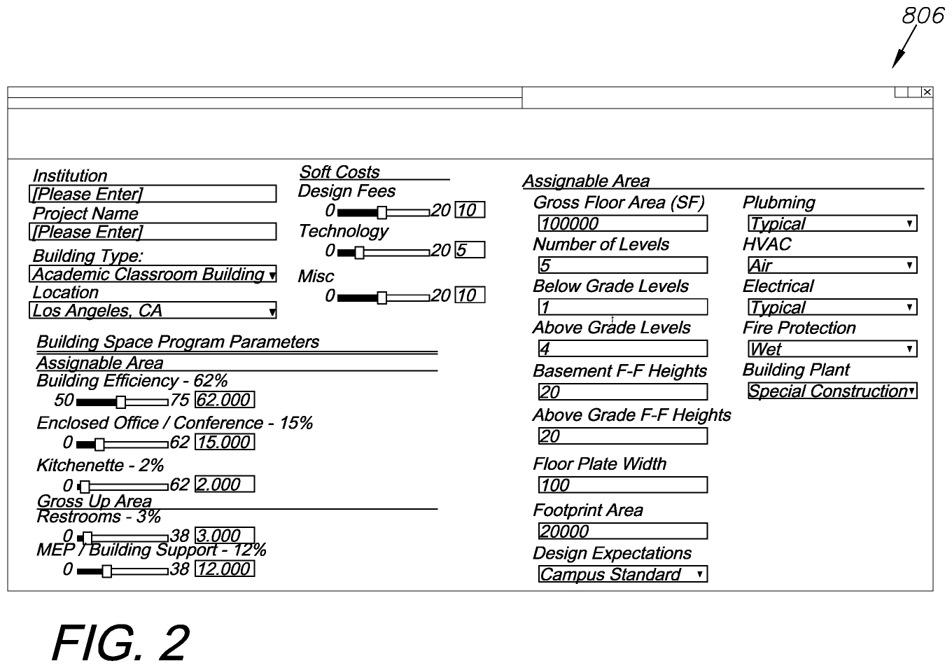

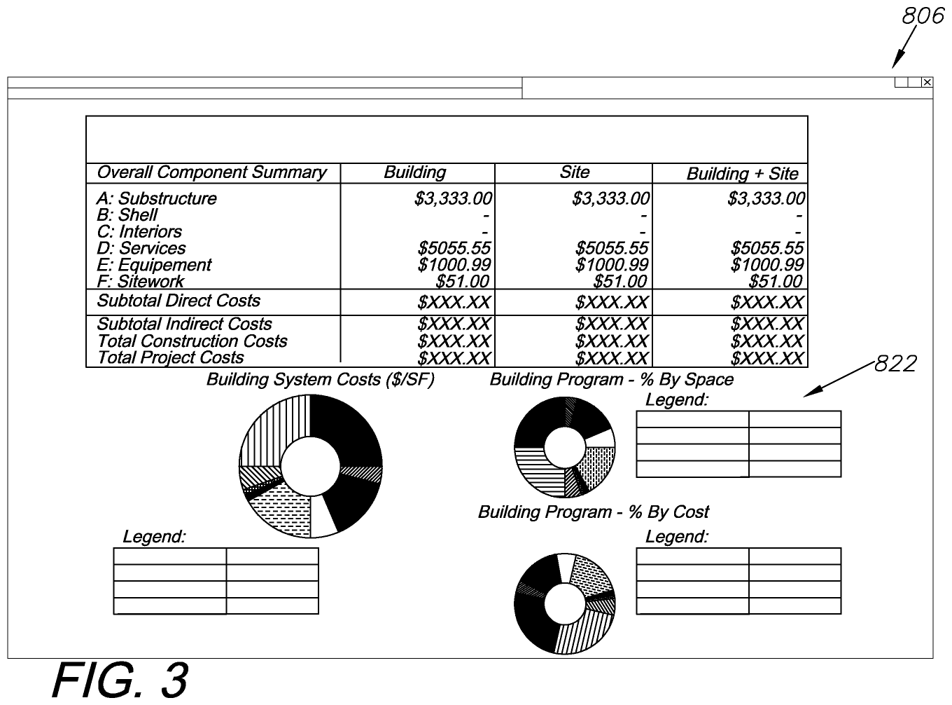

As shown in FIG. 1, a CAD software system 804 can display on a user interface 810 a model 812 generated upon user input and other data. The model includes several properties, including dimension properties 814, material properties 816, and use properties 818. This data is utilized by the estimate software solution 806 to produce the final estimate solution 822. FIG. 2 shows additional user inputs on a user interface 810 which may adjust the properties of the CAD model. FIG. 3 shows a user interface 810 displaying the estimate solution 822 in a detailed breakdown based upon the model properties.

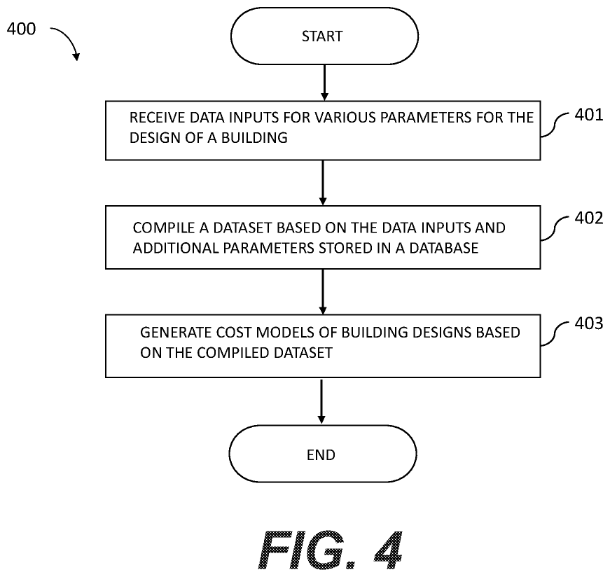

FIGS. 4-7 show various step-by-step processes in which the present invention can be used to generate a cost estimate solution 822 based upon the CAD model and other data.

For example, FIG. 4 shows a method process 400 which starts at a first step 401 where data inputs are received for various parameters for the design of the building. These can be user input or may be determined directly from a CAD model imported or generated by the user. A dataset is compiled based on the data inputs and additional parameters stored in an accessible database at 402. A cost model of the building design based upon this compiled dataset can be generated at 403 and the process ends.

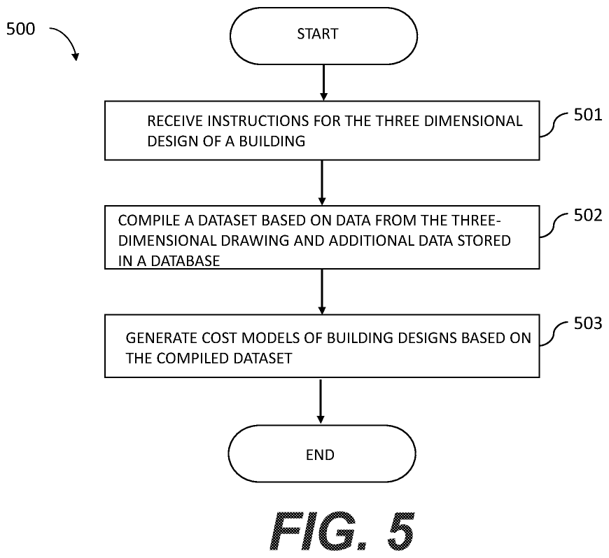

FIG. 5 similarly shows a method process 500 which starts at a step 501 which receives instructions for the three-dimensional design of a building, likely in the form of a 3D CAD model. Again, a dataset is compiled based on the 3D CAD model and additional parameters stored in an accessible database at 502. A cost model of the building design based upon this compiled dataset can be generated at 503 and the process ends.

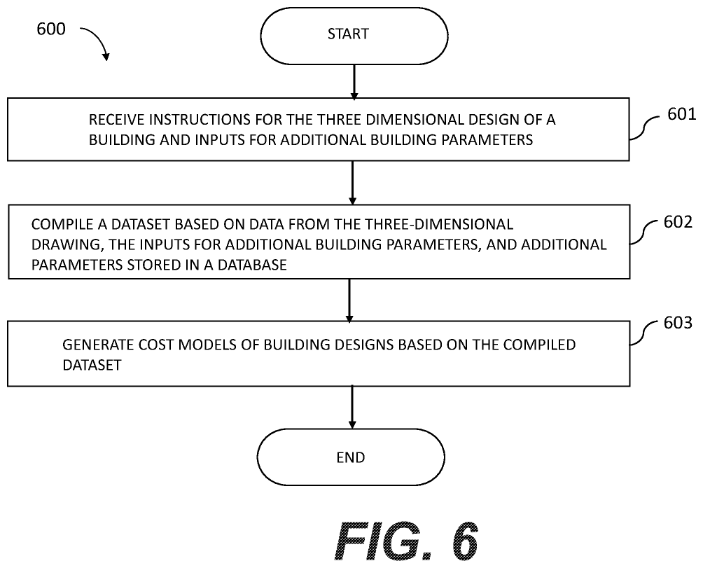

FIG. 6 shows a method process 600 which starts at a first step 601 where instructions are received for a three-dimensional design of a building, along with additional input variables. These can be user input or may be determined directly from a CAD model imported or generated by the user. A dataset is compiled at 602 based on data from the three-dimensional drawing generated at step 601, along with additional parameters stored in an accessible database. A cost model of the building design based upon this compiled dataset can be generated at 603 and the process ends.

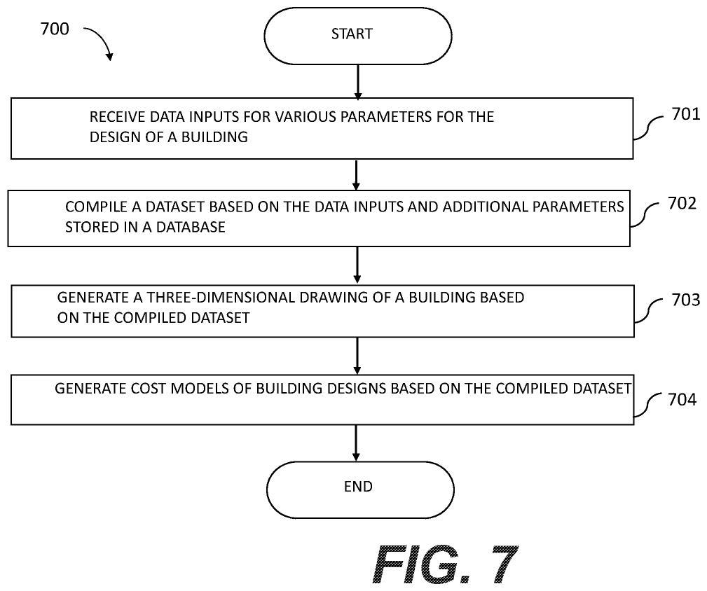

FIG. 7 again shows a method process 700 which starts at a first step 701 where data inputs for various parameters of a building design are received. A dataset is compiled at 702 based upon the data inputs and additional parameters stored within an accessible database. A three-dimensional drawing is generated at 703 based upon the compiled data, either automatically or through user inputs. A cost model of the building design based upon this compiled dataset can be generated at 704 and the process ends.

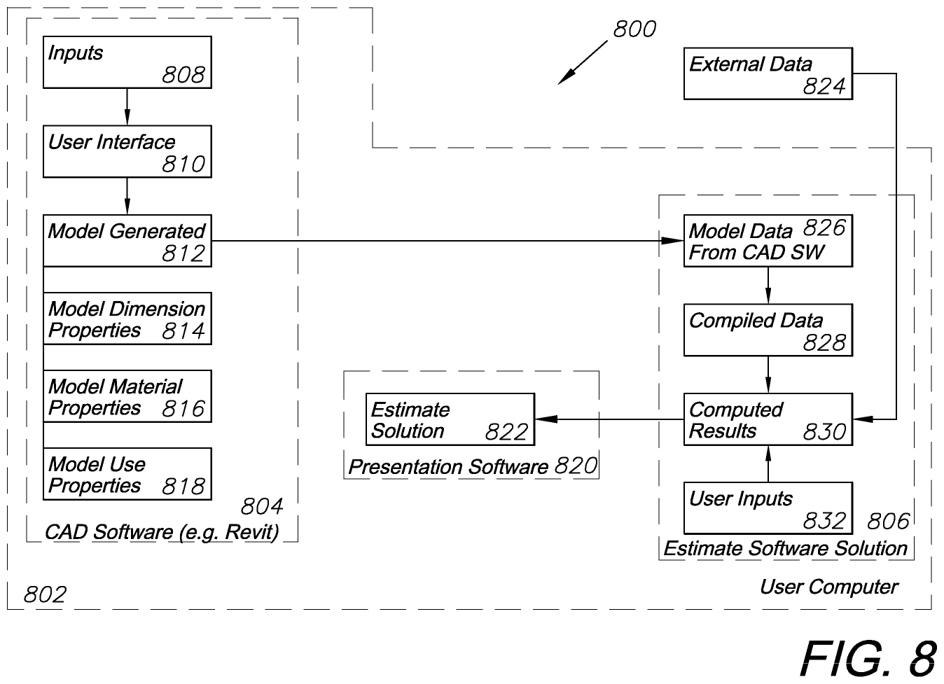

FIG. 8 shows the relationship between the 3D drawing (CAD) software 804 and the cost estimating software 806 in a typical computer-based software system 800. The CAD software 804 includes user inputs 808 into a user interface 810 to generate a model 812. This model includes the various data elements as discussed above, including room dimensions (dimension properties 814), materials (material properties 816), and use properties 818 of the structure being modeled. This data is pulled from the CAD software 804 to the cost estimating software 806. The imported model data from the CAD software 826, the compiled data 828 generated from the CAD model data, user input data, or other non-external data, additional user inputs 832. This all is compiled with the external data points 824 into a computed result 830 which is used to generate a final estimate solution 822, generally provided in some sort of presentation software 820 format, such as a Microsoft® PowerPoint® presentation, .pdf file, printed booklet, or other suitable format.

FIG. 8 further shows elements of the estimate software solution 806, including the imported model data from the CAD software 826, the compiled data 828 generated from the CAD model data, user input data, or other non-external data, additional user inputs 832, and the compiled results 830 from all of those data sources which then is turned into the final estimate solution 822.

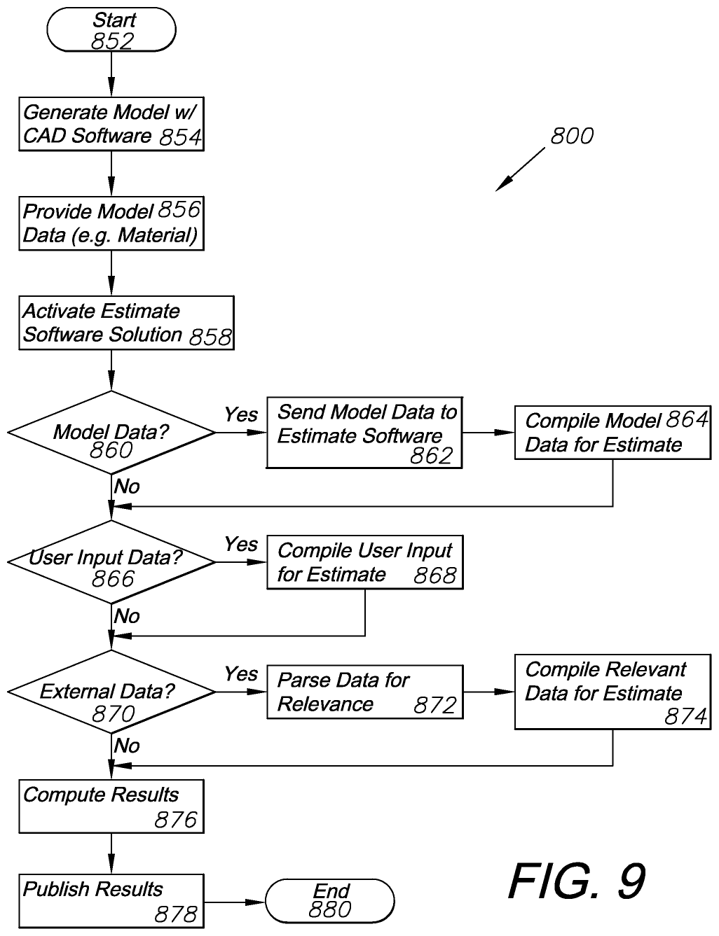

FIG. 9 steps through another method process of practicing an embodiment of the software system 800. The method starts at 852 and a building model is generated using CAD software at 854. The model data is provided either when the model is generated or after the fact at 856. The estimate software solution is then activated at 858. If model data is present at 860, that model data is sent to the estimate software at 862 for compiling for a final estimate solution at 864. As discussed above, this model data could be inherent in the 3D CAD model generated by the user or may be input after the fact. This model data can include material data, use data, dimension data, and other relevant data associated with the final structure being designed.

If user input data exists at 866, that data is also compiled with any model data at 868. Similarly, if any external data exists at 870 from other databases not specifically associated with the present model, that data can be parsed for relevance at 872 and compiled into the estimate solution at 874. Once all data sources are compiled, the system computes the results at 876 and publishes them to the user via the user interface or through another suitable publishing solution at 878. The process then ends at 880.

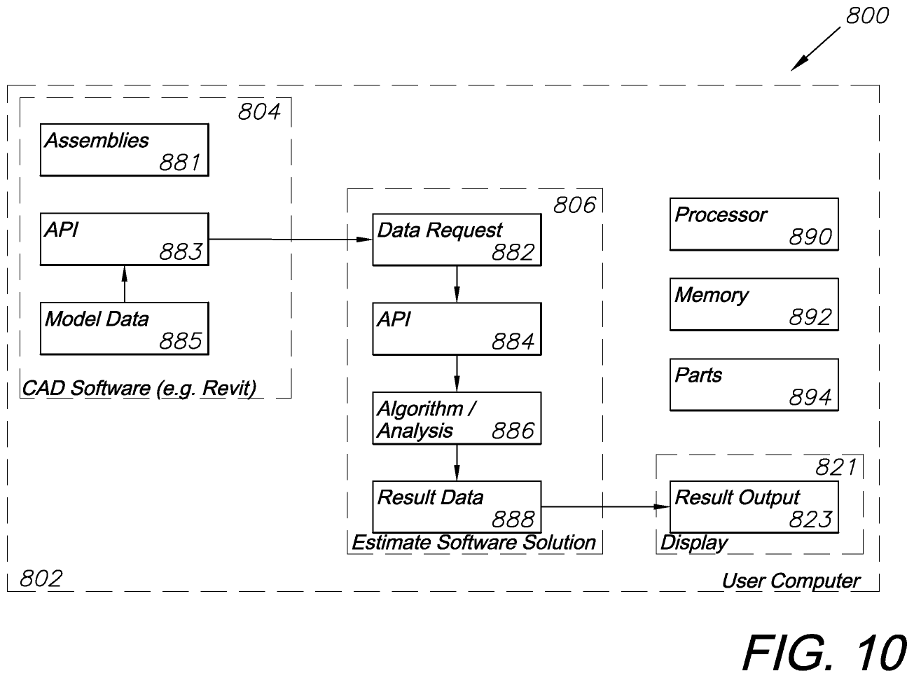

FIG. 10, shows the computing device 802 housing the various software 804, 806 and hardware (e.g. display 821) necessary to operate the cost estimating software 806 and the CAD software 804. In the exemplary embodiment, all of the software and hardware are located on a single computing device; however, the various software elements could be stored on separate computing devices and the data can be communicated between the multiple computing devices through a network or by other suitable data transfer means.

As shown the CAD software 804 includes the assemblies 881 and model data 885. An application programming interface (API) 883 allows this data to be extracted using the estimate software solution 806. A data request 882 from the estimate software solution pulls this data from the CAD software. A second API 884, along with specifically designed algorithms and analysis 886 for producing a cost estimate produces result data 888 which can be used to form the final result output 823 shown on the display 821. The computer also must include a processor 890, data storage (e.g. “memory”) 892, and other necessary parts 894 including devices for receiving user inputs.

The components, steps, features, objects, benefits, and advantages that have been discussed are merely illustrative. None of them, nor the discussions relating to them, are intended to limit the scope of protection in any way. Numerous other embodiments are also contemplated. These include embodiments that have fewer, additional, and/or different components, steps, features, objects, benefits, and/or advantages. These also include embodiments in which the components and/or steps are arranged and/or ordered differently.

Unless otherwise stated, all measurements, values, ratings, positions, magnitudes, sizes, and other specifications that are set forth in this disclosure are approximate, not exact. They are intended to have a reasonable range that is consistent with the functions to which they relate and with what is customary in the art to which they pertain.

All articles, patents, patent applications, and other publications that have been cited in this disclosure are incorporated herein by reference.

In this disclosure, the indefinite article “a” and phrases “one or more” and “at least one” are synonymous and mean “at least one.”

Relational terms such as “first” and “second” and the like may be used solely to distinguish one entity or action from another, without necessarily requiring or implying any actual relationship or order between them. The terms “comprises,” “comprising,” and any other variation thereof when used in connection with a list of elements in the specification or claims are intended to indicate that the list is not exclusive and that other elements may be included. Similarly, an element preceded by an “a” or an “an” does not, without further constraints, preclude the existence of additional elements of the identical type.

The abstract is provided to help the reader quickly ascertain the nature of the technical disclosure. It is submitted with the understanding that it will not be used to interpret or limit the scope or meaning of the claims. In addition, various features in the foregoing detailed description are grouped together in various embodiments to streamline the disclosure. This method of disclosure should not be interpreted as requiring claimed embodiments to require more features than are expressly recited in each claim. Rather, as the following claims reflect, inventive subject matter lies in less than all features of a single disclosed embodiment. Thus, the following claims are hereby incorporated into the detailed description, with each claim standing on its own as separately claimed subject matter.

It is to be understood that while certain embodiments and/or aspects of the invention have been shown and described, the invention is not limited thereto and encompasses various other embodiments and aspects.

Having thus described the invention, what is claimed as new and desired to be secured by Letters Patent is:

1. A cost modeling computing system comprising:
a computer having at least one processor, a data storage, and a non-transitory computer-readable medium;
a first data set comprising data inputs provided into a user interface;
a second data set comprising geometric data elements, use-based data elements, and material data elements of a three-dimensional computer-aided design (CAD) model;
where said geometric data elements, use-based data elements, and material data elements are configured to represent characteristics associated with a final building design represented by and stored within said three-dimensional CAD model;
said second data set associated with physical parameters of a structure to be constructed;
wherein said at least one processor is configured to compile a dataset based upon said first data set and said second data set; and
wherein said at least one processor is further configured to provide a cost estimate of said structure based upon data set and said second data set.

2. The system of claim 1, further comprising:
said processor configured to produce a three-dimensional drawing of said structure based upon said first data set and said second data set; and
said processor further configured to produce said three-dimensional drawing on a display connected to said computer.

3. The system of claim 1, wherein said computer comprises a first computer, the system further comprising:
a second computer comprising at least one processor, a data storage, and a communications link;
said first computer comprising a communications link; and
wherein said first computer is configured to transmit said cost estimate from said first computer to said second computer.

4. The system of claim 1, wherein the received data includes data obtained from the three-dimensional CAD model and a plurality of parameters of a building distinct from the data obtained from the three-dimensional CAD model.

5. The system of claim 1, further comprising:
a third data set comprising external data from said computer; and
wherein said external data is selected from the list comprising: construction schedule, soft costs; building space program parameters; and building system parameters.

6. The system of claim 1, further comprising:
a third data set comprising a construction schedule including data selected from the list comprising: escalation date; construction start date; construction duration; construction contingency; and escalation contingency.

7. The system of claim 1, further comprising:
a third data set selected from the list comprising: design fees; FFE; technology; miscellaneous; and contingency.

8. The system of claim 1, further comprising:
a third data set selected from the list comprising: design fees; FFE; technology; miscellaneous; and contingency.

9. The system of claim 1, further comprising:
a third data set selected from the list comprising: building efficiency; enclosed office; kitchenette; teaching space; open office; and shell space.

10. The system of claim 1, wherein said second data set includes data selected from the list comprising: gross floor area; number of levels; below grade levels; above grade levels; basement floor-to-floor heights; above grade floor-to-floor heights; floor plate width; footprint area; design expectations; performance criteria; cladding ratio; glazing ratio; vertical surface articulation factor, horizontal surface articulation factor; roof terrace ratio; roof glazing ratio; floor structure type; roof structure type; site constraint; and soil condition.

11. A non-transitory computer readable medium usable by a computer that includes a processor and a memory, the medium comprising:
an add-on computer software code that runs as an internal component within a software design tool on the computer;
wherein execution of the add-on computer software code by the processor causes the computer to generate a cost estimate for a three-dimensional building model created by the software design tool, by at least:
transmitting data corresponding to one or more building design parameters from the building model to a database storing parameters related to building costs;
receiving from the database data for parameters related to building costs; and
generating a cost estimate from the transmitted data and the received data.

12. A cost modeling computing system comprising:
a computing device including a respective central processing unit (CPU), data storage, and a graphical user interface (GUI);
a computer-aided design (CAD) model generated with a CAD software program stored on said data storage and accessible by said CPU;
said CAD model configured to be generated based upon inputs into said computing device interpreted by said CPU and displayed on said GUI;
said CAD model comprising material properties, dimensional properties, and use properties associated with a structure to be constructed;
an estimate software solution stored on said data storage and accessible by said CPU;
said estimate software solution configured to receive said material properties, dimensional properties, and use properties;
said estimate software solution further configured to automatically calculate and generate an estimate solution based upon said material properties, dimensional properties, and use properties; and
said estimate software solution further configured to display said estimate solution on said GUI in real time as said CAD model is updated.
